(19) United States
(12) Patent Application Publication
(10) Pub. No.: US 2006/0021735 A1
(43) Pub. Date: Feb. 2, 2006

(54) Integrated cooler for electronic devices

(75) Inventors: Edward Lopatinsky, San Diego, CA (US); Lev Fedoseyev, El Cajon, CA (US)

Correspondence Address: Edward Lopatinsky, 5450 Complex str. # 307, San Diego, CA, 92123, US

(73) Assignee: Industrial Design Laboratories Inc.

(21) Appl. No.: 11/185,378

(22) Filed: Jul. 20, 2005

Related U.S. Application Data
(60) Provisional application No. 60/591,492, filed on Jul. 27, 2004.

(51) Int. Cl. H05K 7/20

(52) U.S. Cl. 165/80.3; 165/122; 361/697

(57) ABSTRACT

An integrated cooler comprises a heatsink integrated with a centrifugal blower. The heatsink comprises a base and heat exchanging means. The centrifugal blower comprises an electric motor, a casing with inlet and at least one outlet, a radial impeller and an axle. The electric motor comprises a magnetized rotor and a flat stator with an opening coincided with blower inlet thus the stator serves as an upper side of the casing. The base made as a lower side of the casing and provides thermal contact with the electronic device and the heat exchanging means. The radial impeller comprises magnetic means thus serving as the magnetized rotor. The heat exchanging means located inside of the radial impeller and surrounded by the blades thus cooling gas flows through the blower inlet, the heat exchanging means, the radial impeller and the at least one blower outlet in a series way.

### CROSS REFERENCE TO RELATED APPLICATIONS

The present application claims the benefit of priority of U.S. Provisional Patent Application No. 60/591,492, filed Jul. 27, 2004 for Edward Lopatinsky at al. the entire content of which is incorporated herein by reference.

### FIELD OF THE INVENTION

The present invention relates generally to cooling systems. More particularly, the present invention relates to cooling systems for regulating the temperature of electronic components. The present invention is particularly, but not exclusively, useful for a cooling system for regulating the temperature of electronic components of a Graphic Processor Unit (GPU).

### BACKGROUND OF THE INVENTION

The regulation of the temperature due to heat generated inside the housing of an electronic device like GPU is an important consideration during the design of an electronic device. Cooling is important because if left unchecked, heat can cause electronic devices to malfunction during use or lead to premature device failure. As improvements in processor size and speed occur, the amount of heat generated by the larger and faster processors also increases. Additionally, improved processors require larger power supplies and auxiliary components that generate increased amounts of heat and require improved systems for heat removal.

Another factor that aggravates the need for improved heat removal cooling systems is the trend towards making computing devices such as GPU smaller and especially thinner. The trend toward smaller and thinner electronic devices having larger, faster processors renders the traditional heat removal cooling systems inadequate for several reasons. First, smaller devices having faster processors result in an increased density of heat producing electronic components leading to higher localized concentrations of heat. Also, a decreased amount of space is available for localized temperature regulating devices such as traditional heat sinks. Lastly, a decreased amount of space is available to create ventilation paths that pass by heat sources.

In order to enhance the cooling capacity of a cooling device, an electrically powered blower is often mounted within or on top of a heatsink of the cooling device. In operation, the blower forces air to pass over fins of the heatsink, thus, cooling the heatsink by enhancing the heat transfer from the fins into the ambient air.

There are known devices of this type, for example, U.S. Pat. No. 6,688,379 “Heat Dissipation Device with High Efficiency”. The device described in this U.S. patent comprises a radial blower that produces a flow passing by heat exchanging channels of the heatsink. The radial blower comprises conventional hub electric drive spaced at a flowing part inside of a radial impeller thus restrains the air flow and therefore decrease the total amount of air passing through the heatsink. By this reason, the thermal efficiency of this heat dissipation device is insufficient.

Due to modern requirements for cooling devices, especially in respect to a combination of the thermal efficiency and an available space, flat electric drives are often used in radial blowers for cooling of electronic components. There are such devices describe in U.S. Pat. No. 6,664,673 “Cooler for Electronic Devices” and U.S. Pat No. 6,700,781 “Heat-Dissipating Module for Removing Heat Generated from Heat-Generating Device”. Both above mentioned inventions comprise a flat stator plate made as circuit board and a magnetized rotor fixed to a radial impeller of the blower. The flat stator and the magnetized rotor are located in two different parallel planes and separated by an air gap. For further utilizing of available space heat exchanging means located inside of a radial impeller.

However, arrangement of electric drive inside blower casing according U.S. Pat. No. 6,700,781 requires additional space increasing a thickness of the cooling device and cause a vibration of the flat stator and magnetized rotor due to a rise of oscillation forces in a direction perpendicular to the planes of the flat stator and the magnetized rotor. These forces determine by an interaction between magnetic poles of the stator and rotor. In one's turn the vibration generates an increasing sound level thus contradicts with modern requirements for cooling devices.

On the other hand mentioned vibration cause an energy losses thus decrease the motor efficiency of the electric drive and, correspondingly, a blower efficiency.

Described design of the cooler according to U.S. Pat. No. 6,664,673 comprises the flat stator placed between two symmetrical magnetized rotor-disks, thus decrease the mentioned vibration of the flat stator and magnetized rotor but increase the thickness of the electric drive.

For cooling of modern GPU conventional cooling devices may comprise additional heatsinks mounted at auxiliary heat generated components. There is known device of this type described in U.S. patent application No 2002/0172008 “High-performance heat sink for printed circuit board”. However, according to this design main and additional heat exchanging means located outside of the radial impeller thus significantly increase a space required for such devices.

Therefore, it would be desirable to provide a cooler for electronic devices that would overcome these problems associated with available space, increased sound level and decreased blower efficiency.

### SUMMARY OF THE INVENTION

Accordingly, it is an object of the present invention to provide an integrated cooler for electronic devices, which is capable of significantly improving of cooler performances such as small required space, high thermal efficiency, low sound level and increased blower efficiency.

In order to achieve this object, the integrated cooler for electronic devices comprises a heatsink integrated with a centrifugal blower. The heatsink comprises a base and heat exchanging means, the centrifugal blower comprises an electric motor, a casing with inlet and at least one outlet, a radial impeller and an axle. The electric motor comprises a magnetized rotor and a flat stator with an opening coincided with blower inlet thus the stator serving as an upper side of the casing. The base made as a lower side of the casing and provides thermal contact with the electronic device and the heat exchanging means. The impeller comprises blades, a shroud and magnetic means thus serving as said magnetized rotor. The heat exchanging means located inside of the radial impeller and surrounded by the blades thus cooling gas flows through the blower inlet, the heat exchanging means, the radial impeller and the at least one blower outlet in a series way.

There are some variants of the electric motor. First, the stator may comprise coils etched on a printed circuit board with magnetic axes perpendicular to a plane of the flat stator and the magnetic means magnetized in direction perpendicular to the plane of the flat stator. Second, the flat stator may comprise circumferential arrayed coils windings with magnetic axes being coincide with a plane of the flat stator and the magnetic means placed and magnetized along the plane of the flat stator thus magnetic axes of the coils windings and the magnetic means located at one plane substantially.

There are two options for heat exchanging means. The heat exchanging means may be made as pins or made as spiral fins curved in direction of rotation of the radial impeller. For achieve a smooth and even airflow along the spiral fins last ones spaced apart at equal distance.

The magnetic means may be made as the blades or shroud of the impeller.

The integrated cooler for electronic devices may further comprises additional heat exchanging means thermally connected with the casing and located at the at least one outlet thus cooling gas flows through the blower inlet, the heat exchanging means, the radial impeller, the additional heat exchanging means and the at least one outlet in a series way.

There are some options for additional heat exchanging means. According to the first option the additional heat exchanging means made as shaped fins parallel or perpendicular to the base of the casing. And according to the second option the additional heat exchanging means made as pins structure.

In case when there are at least two electronic devices need for cooling the integrated cooler may further comprise at least one additional heatsink thermally connected with one of the electronic devise and placed at the at least one outlet thus cooling gas flows through the blower inlet, the heat exchanging means, the radial impeller, at least one blower outlet and the additional heatsink in a series way. The additional heatsink comprises heat exchanging elements and a plate provided thermal contact with one of the electronic devise and the heat exchanging elements. The heat exchanging elements may be made as pins-fins structure or as fins placed along the direction of cooling gas flows through the at least one outlet.

### BRIEF DESCRIPTION OF THE DRAWINGS

FIG. 1 is a perspective view showing the integrated cooler for electronic devices;

FIG. 2 is an exploded view showing the integrated cooler for electronic devices;

FIG. 3 is a perspective view showing the integrated cooler for electronic devices with the second variant of the electric motor;

FIG. 4 is an exploded view showing the integrated cooler for electronic devices with the second variant of the electric motor;

FIG. 5 is a perspective view showing the second variant of the electric motor;

FIG. 6 is a perspective view showing the integrated cooler for electronic devices with heat exchanging means made as pins;

FIG. 7 is an exploded view showing the integrated cooler for electronic devices with additional heat exchanging means made as shaped fins parallel to the base;

FIG. 8 is an exploded view showing the integrated cooler for electronic devices with additional heat exchanging means made as shaped fins perpendicular to the base;

FIG. 9 is a perspective view showing the integrated cooler for electronic devices with additional heatsink;

FIG. 10 is an exploded view showing the integrated cooler for electronic devices with additional heatsink;

FIG. 11 is a bottom perspective view showing the integrated cooler for electronic devices with additional heatsink;

FIG. 12 is a perspective view showing the integrated cooler for electronic devices with additional heatsink when heat exchanging elements made as fins.

### DETAILED DESCRIPTION OF PREFERRED EMBODIMENTS

Preferred embodiment of the present invention will be described in detail below with reference to the accompanying drawings. The numbering of components is consistent throughout, with the same components having the same number.

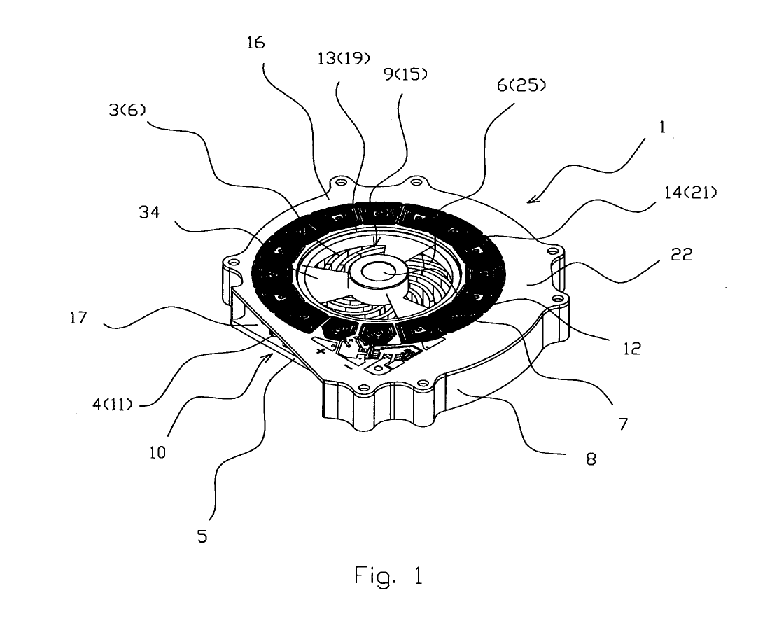

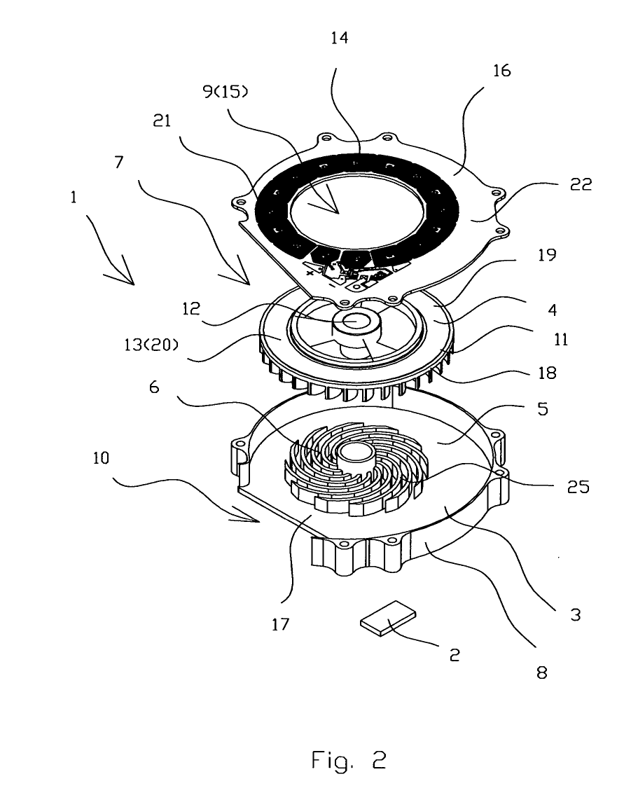

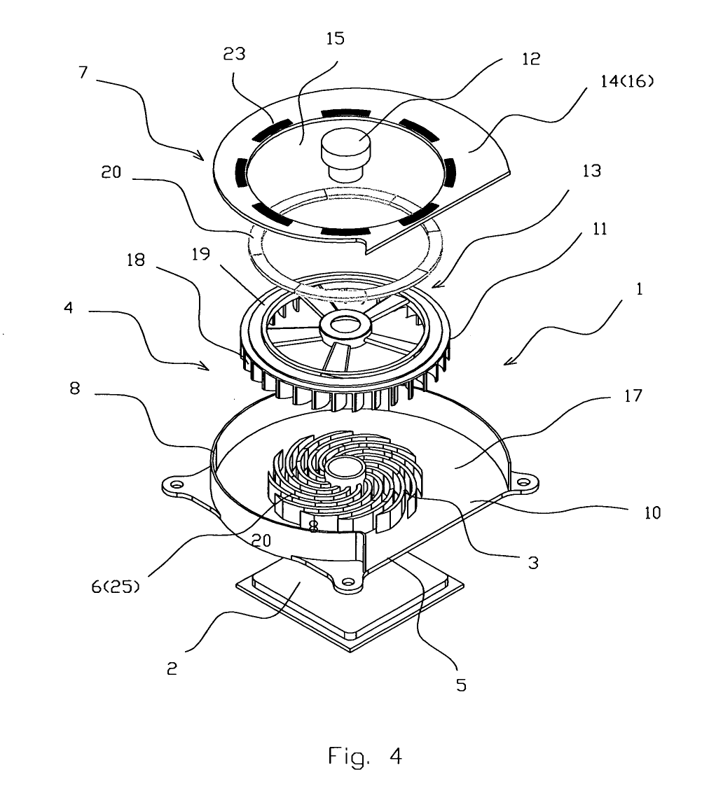

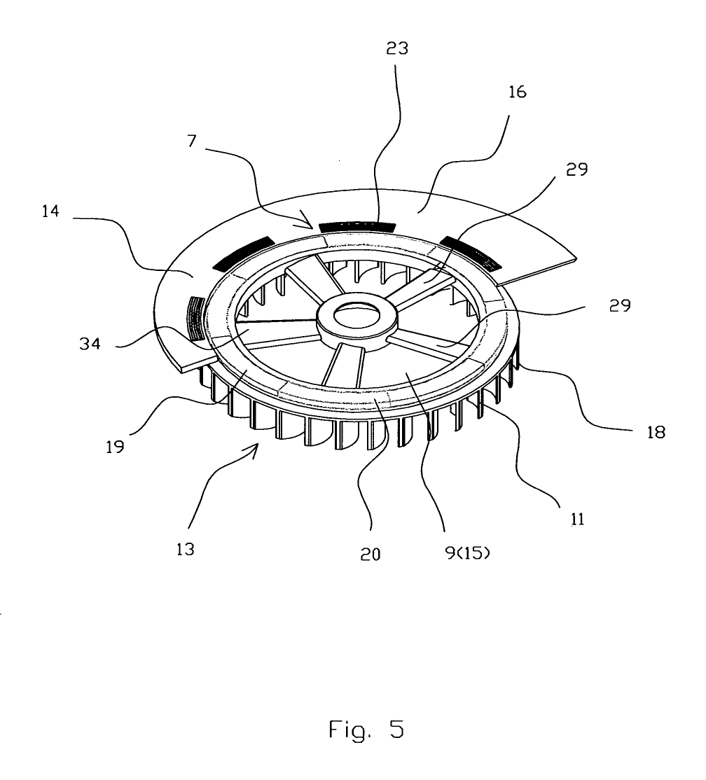

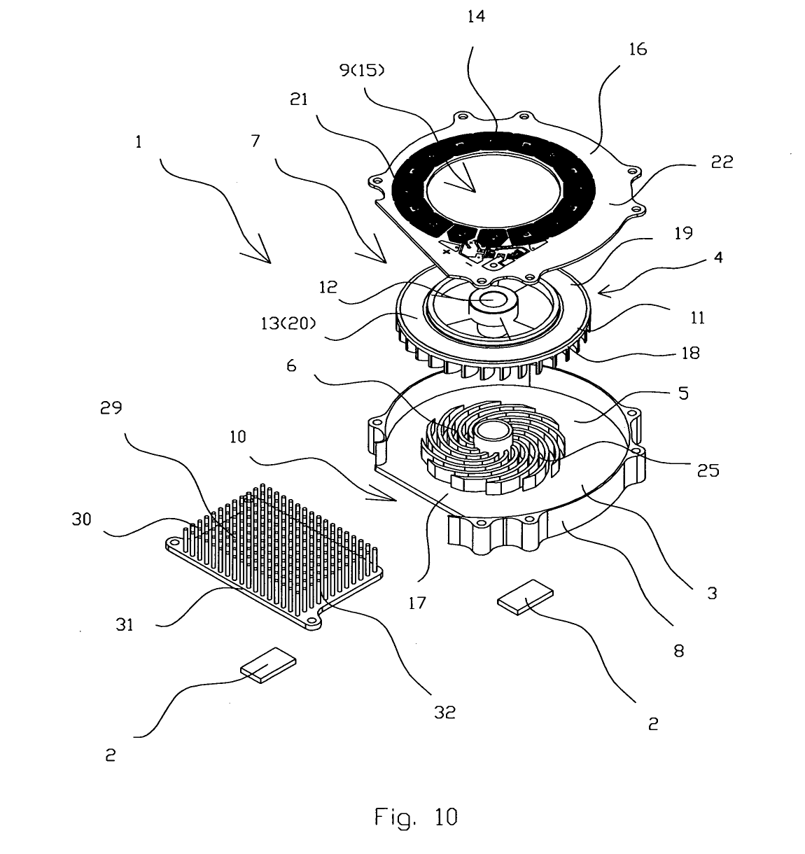

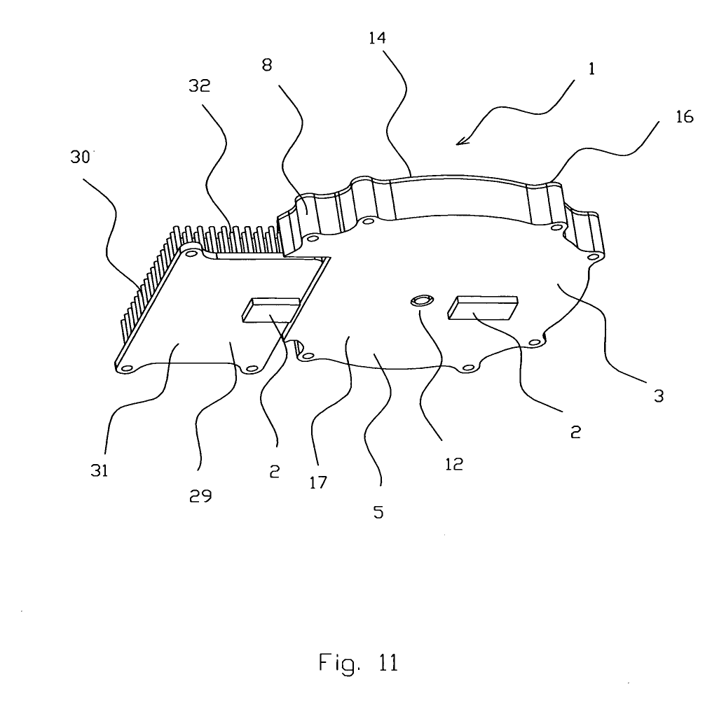

FIGS. 1-12 show an embodiment of the present invention.

The integrated cooler 1 for electronic devices 2 (FIGS. 1-4 and 6-12) comprises a heatsink 3 integrated with a centrifugal blower 4. The heatsink 3 comprises a base 5 and heat exchanging means 6. The centrifugal blower 4 comprises an electric motor 7, a casing 8 with inlet 9 and at least one outlet 10, a radial impeller 11 and an axle 12. The electric motor 7 comprises a magnetized rotor 13 and a flat stator 14 with an opening 15 coincided with blower inlet 9 thus the stator 14 serves as an upper side 16 of the casing 8. The base 5 made as a lower side 17 of the casing 8 and provides thermal contact with the electronic device 2 and the heat exchanging means 6. The impeller 11 comprises blades 18, a shroud 19 and magnetic means 20 thus the impeller 11 serves as the magnetized rotor 13. The heat exchanging means 6 located inside of the radial impeller 11 and surrounded by the blades 18 thus cooling gas flows through the blower inlet 9, the heat exchanging means 6, the radial impeller 11 and at least one blower outlet 10 in a series way.

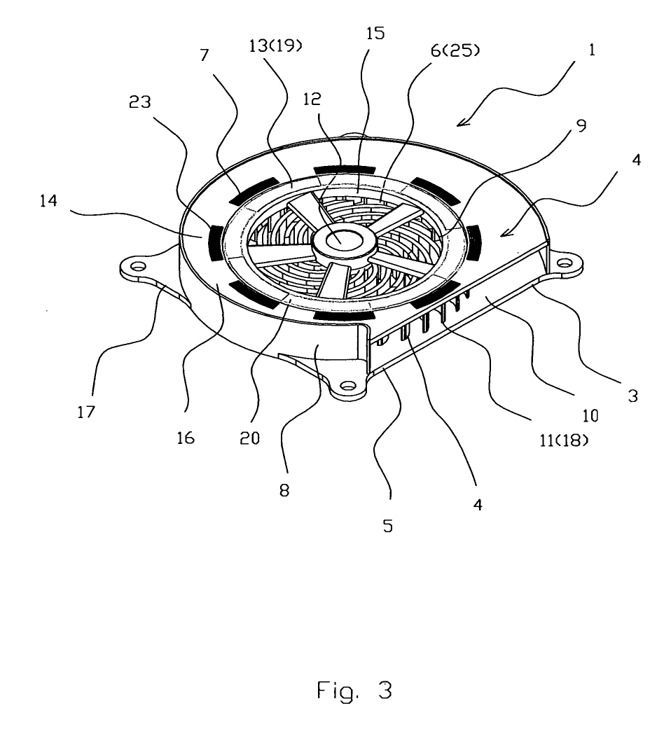

According to the first variant of the electric motor 7 (FIGS. 1, 2, 6, 9, 10 and 12) the flat stator 14 comprises coils 21 etched on a printed circuit board 22 with magnetic axes perpendicular to a plane of the flat stator 14 and the magnetic means 20 magnetized in direction perpendicular to the plane of the flat stator 14. And, according to the second variant of the electric motor 7 (FIGS. 3-5, 7 and 8) the flat stator 14 comprises circumferential arrayed coils windings 23 with magnetic axes coincide with a plane of the flat stator 14 and the magnetic means 20 placed and magnetized along the plane of the flat stator 14 thus magnetic axes of the coils windings 23 and the magnetic means 20 located at one plane substantially.

The first variant of the electric motor 7 characterized by some decreasing of the sound level due to the integrated of the printed circuit board 22 with the upper side 16 of the casing 8. It is explained by increasing of a rigidity of such type design of a stator. But, according to the second variant of the electric motor 7 the magnetic means 20 placed and magnetized along the plane of the flat stator 14 thus magnetic axes of the coils windings 23 and the magnetic means 20 located at one plane substantially. Therefore, is no reason for rise of oscillation forces in a direction perpendicular to the planes of the flat stator 14 and the magnetized rotor 13. By this reason there is no vibration and this variant of the electric motor 7 characterized by lower sound level and higher motor efficiency.

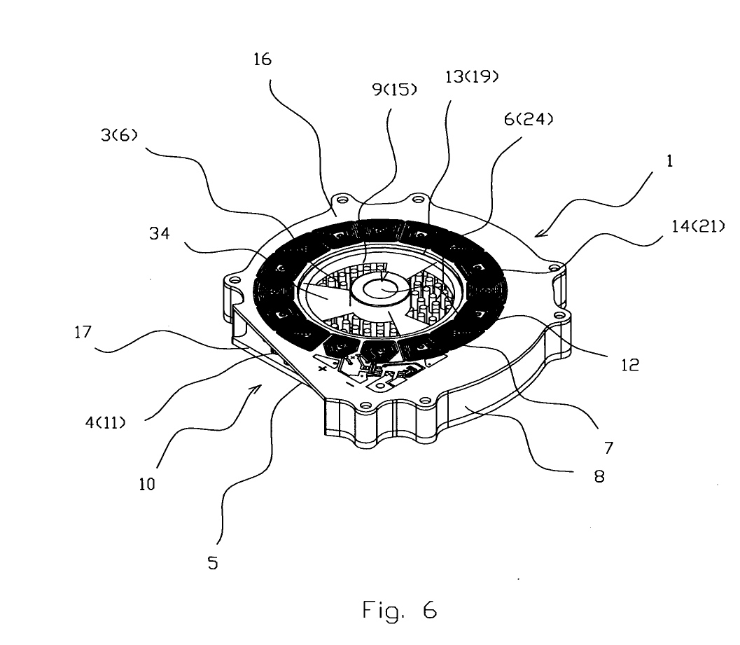

There are two options for heat exchanging means 6. The heat exchanging means 6 may be made as pins 24 (FIG. 6) or made as spiral fins 25 (FIGS. 1-4, 7-10 and 12) curved in direction of rotation of the radial impeller 11. For achieve a smooth and even airflow along the spiral fins 25 last ones may be spaced apart at equal distance.

The magnetic means 20 may be made as the blades 18 or shroud 19 of the radial impeller 11.

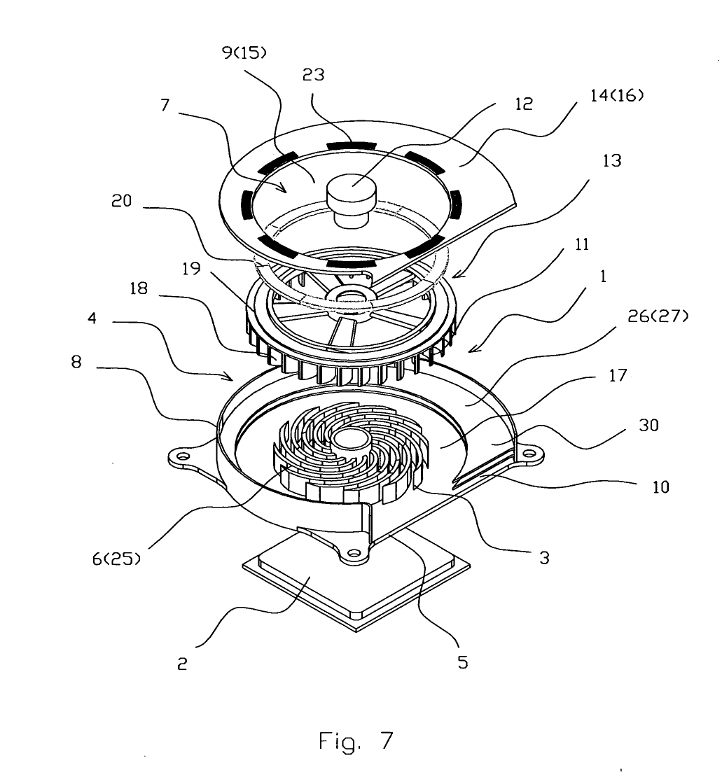

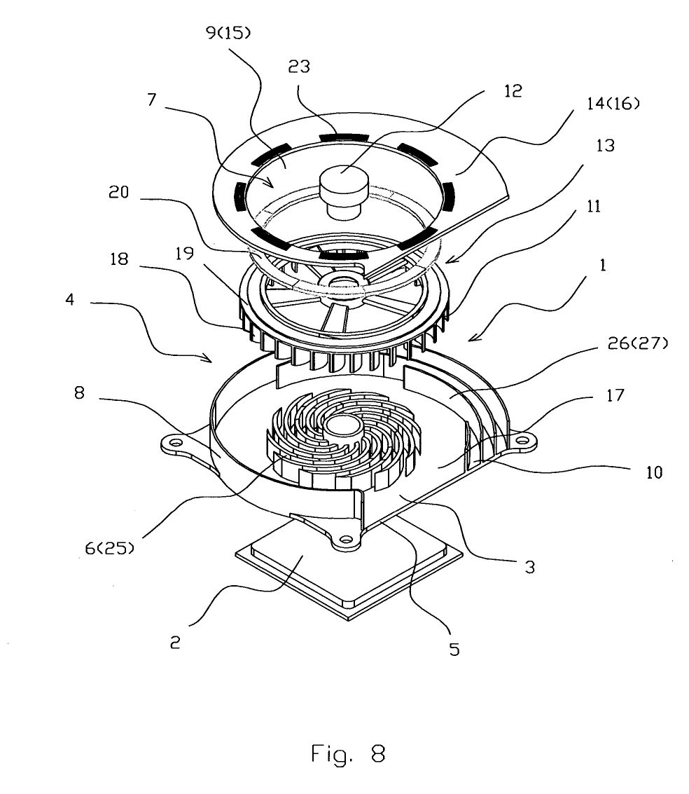

For increasing a heat exchange surface the integrated cooler 1 for electronic devices 2 may further comprises additional heat exchanging means 26 thermally connected with the casing 8 and located at the at least one outlet 10 (FIGS. 7 and 8) thus cooling gas flows through the blower inlet 9, the heat exchanging means 6, the radial impeller 11, the additional heat exchanging means 26 and the at least one outlet 10 in a series way.

There are some options for the additional heat exchanging means 26. According to the first option the additional heat exchanging means 26 made as shaped fins 27 parallel (FIG. 7) or perpendicular (FIG. 8) to the base 5, of the casing 8. And according to the second option the additional heat exchanging means 26 may be made as pins structure (not shown on Figs.).

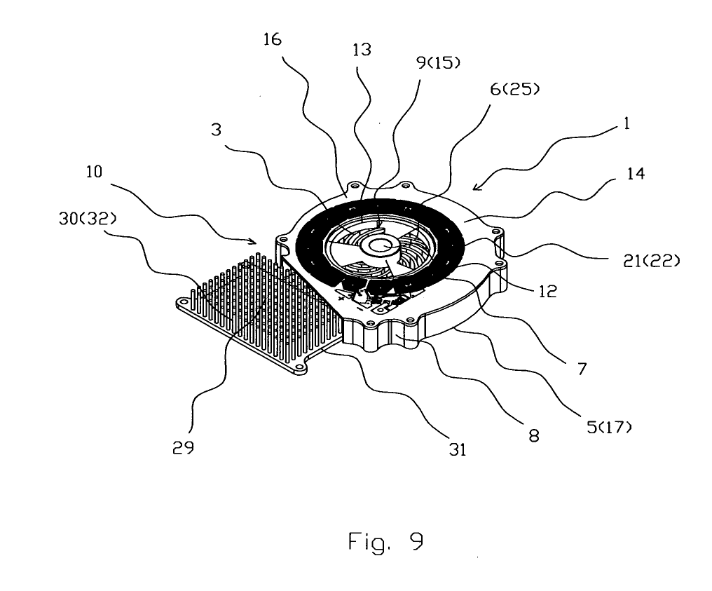

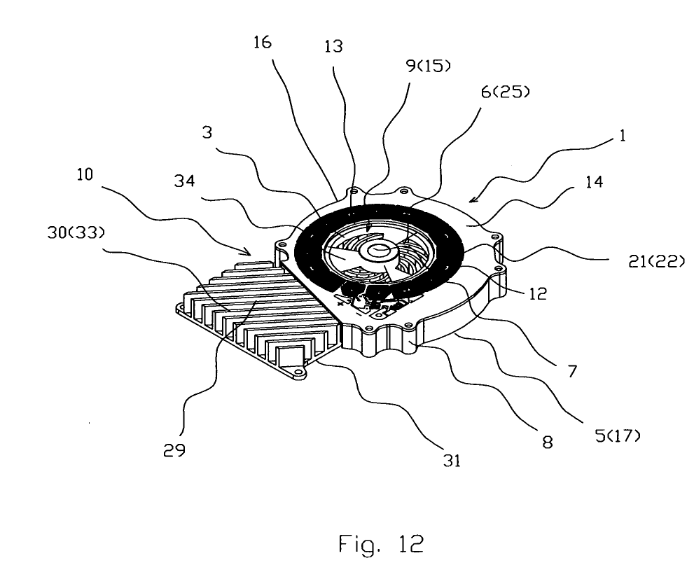

In case when there are at least two electronic devices 2 (FIGS. 9-12) need for cooling the integrated cooler 1 may further comprise at least one additional heatsink 29 thermally connected with one of the electronic devise 2 and placed at the at least one outlet 10 thus cooling gas flows through the blower inlet 9, the heat exchanging means 6, the radial impeller 11, at least one blower outlet 10 and the additional heatsink 29 in a series way. The additional heatsink 29 comprises heat exchanging elements 30 and a plate 31 provided thermal contact with one of the electronic devise 2 and the heat exchanging elements 30. The heat exchanging elements 30 may be made as pins-fins structure 32 (FIGS. 9-11) or as fins 33 placed along the direction of cooling gas flows through the at least one outlet 10 (FIG. 12).

For some additional increasing amount of air the radial impeller 11 fixed to the axle 12 by axial blades 34.

The integrated cooler for electronic devices according to the present invention characterized by smaller required space, especially by thickness dimension; by low sound level and by higher blower efficiency in comparison with conventional coolers.

What is claimed is:

1. An integrated cooler for electronic devices comprising:
a heatsink being integrated with a centrifugal blower, wherein
(i) said heatsink comprising a base and heat exchanging means;
(ii) said centrifugal blower comprising an electric motor, a casing with inlet and at least one outlet, a radial impeller and an axle;
(iii) said electric motor comprising a magnetized rotor and a flat stator with an opening coincided with blower inlet thus said stator serving as an upper side of said casing;
(iv) said base made as a lower side of said casing and provides thermal contact with said electronic device and said heat exchanging means;
(v) said radial impeller comprising blades, a shroud and magnetic means thus serving as said magnetized rotor;
(vi) said heat exchanging means being located inside of said radial impeller and being surrounded by said blades thus cooling gas flows through said blower inlet, said heat exchanging means, said radial impeller and said at least one blower outlet in a series way.

2. The integrated cooler for electronic devices as claimed in claim 1, wherein said stator comprising coils etched on a printed circuit board with magnetic axes being perpendicular to a plane of said flat stator and said magnetic means magnetized in direction perpendicular to said plane of said flat stator.

3. The integrated cooler for electronic devices as claimed in claim 1, wherein said flat stator comprising circumferential arrayed coils windings with magnetic axes being coincide with a plane of said flat stator and said magnetic means being placed and magnetized along said plane of said flat stator thus magnetic axes of said coils windings and said magnetic means being located at one plane substantially.

4. The integrated cooler for electronic devices as claimed in claim 1, wherein said heat exchanging means made as pins.

5. The integrated cooler for electronic devices as claimed in claim 1, wherein said heat exchanging means made as spiral fins curved in direction of rotation of said radial impeller.

6. The integrated cooler for electronic devices as claimed in claim 5, wherein said spiral fins being spaced apart at equal distance.

7. The integrated cooler for electronic devices as claimed in claim 1, wherein said magnetic means made as said blades of said impeller.

8. The integrated cooler for electronic devices as claimed in claim 1, wherein said magnetic means made as said shroud of said impeller.

9. The integrated cooler for electronic devices as claimed in claim 1, further comprising additional heat exchanging means thermally connected with said casing and being located at said at least one outlet thus cooling gas flows through said blower inlet, said heat exchanging means, said radial impeller, said additional heat exchanging means and said at least one outlet in a series way.

10. The integrated cooler for electronic devices as claimed in claim 9, wherein said additional heat exchanging means made as shaped fins parallel or perpendicular to said base of said casing.

11. The integrated cooler for electronic devices as claimed in claim 9, wherein said additional heat exchanging means made as pins structure.

12. The integrated cooler for at least two electronic devices as claimed in claim 1, further comprising at least one additional heatsink thermally connected with one of said electronic devise and being placed at said at least one outlet thus cooling gas flows through said blower inlet, said heat exchanging means, said radial impeller, said at least one blower outlet and said additional heatsink in a series way.

13. The integrated cooler for electronic devices as claimed in claim 12, wherein said additional heatsink comprising heat exchanging elements and a plate provided thermal contact with one of said electronic devise and said heat exchanging elements.

14. The integrated cooler for electronic devices as claimed in claim 13, wherein said heat exchanging elements made as pins-fins structure.

15. The integrated cooler for electronic devices as claimed in claim 13, wherein said heat exchanging elements made as fins being placed along the direction of cooling gas flows through said at least one outlet.
